(19) United States
(12) Patent Application Publication
(10) Pub. No.: US 2016/0133587 A1
(43) Pub. Date: May 12, 2016

(54) SUBSTRATES AND INTEGRATED CIRCUIT CHIP WITH IMPROVED PATTERN

(71) Applicant: Silicon Works Co., Ltd., Daejeon (KR)

(72) Inventors: Sang Young Lee, Jeonju (KR); Gyeong Sik Mun, Daejeon (KR); Ki Chul An, Daegu (KR)

(73) Assignee: Silicon Works Co., Ltd.

(21) Appl. No.: 14/923,722

(22) Filed: Oct. 27, 2015

(30) Foreign Application Priority Data
Nov. 6, 2014 (KR) 10-2014-0153841

(51) Int. Cl. H01L 23/00

(52) U.S. Cl. CPC H01L 24/06; H01L 2924/14; H01L 2224/0603; H01L 2224/06177; H01L 2224/08225; H01L 2224/08245

(57) ABSTRACT

The present invention relates to a substrate and integrated circuit chip with improved patterns, and more particularly to technology that is efficient in terms of thermal control and that can reduce the causes of occurrence of defects during the operation of a terminal to which a high voltage is applied. The present invention is characterized in that a first clearance distance between a first terminal, to which a voltage higher than voltages to be applied to the remaining terminals is applied, or first terminal pattern corresponding to the first terminal and a body pattern present between an integrated circuit chip and a substrate is larger than a second clearance distance between a second terminal, including at least some of the remaining terminals other than the first terminal, or second terminal pattern corresponding to the second terminal and the body pattern.

### CROSS-REFERENCE TO RELATED APPLICATION

This application claims under 35 U.S.C. §119(a) the benefit of Korean Application No. 10-2014-0153841 filed on Nov. 6, 2014, which is incorporated herein by reference.

### TECHNICAL FIELD

The present invention relates to a package substrate and integrated circuit chip with improved patterns, and more particularly to technology that is efficient in terms of thermal control and that can reduce the causes of occurrence of defects during the operation of a terminal to which a high voltage is applied.

### BACKGROUND ART

In efforts to conserve energy, the development of lighting technology using light-emitting diodes (LEDs) as light sources has been ongoing. In particular, high-luminance LEDs have advantages over other light sources in terms of various factors, such as the amount of energy consumption, lifespan, and the quality of lighting.

Lighting devices using such LEDs as light sources are problematic in that a plurality of complicated circuits for maintaining a constant current is required because they can generate a predetermined amount of light only if they are operated using constant current due to the characteristics of LEDs.

Accordingly, technology that has been devised to deal with the above problem is Alternating Current (AC)-direct type lighting.

AC-direct type LED lighting is designed to generate a rectified voltage using commercial AC power and drive LEDs using the rectified voltage. The AC-direct type LED lighting has the characteristic of improving a power factor because it uses a rectified voltage directly as an input voltage without using an inductor and a capacitor.

An example of such an AC-direct type LED device is disclosed in Korean Patent No. 10-1175934 entitled “LED Drive Circuit and AC-direct Type LED Lighting Device using Same.”

According to this preceding technology, the AC-direct type LED device does not include a conversion circuit for converting AC signals into DC signals, and transfers the sine wave curve of AC voltage to LEDs without change. In this case, a high voltage terminal that receives AC voltage and transfers the AC voltage to the LEDs is a terminal to which a voltage that is 1.4 times an AC rated voltage can be applied.

When a high voltage is instantaneously applied to the high voltage terminal, a strong electric field is instantaneously generated between the high voltage terminal and adjacent terminals, with the result that a problem arises in that possibility that a short circuit occurs between the high voltage terminal and the adjacent terminals, between the high voltage terminal and a body pad, between a high voltage terminal pattern on a substrate corresponding to the high voltage terminal and adjacent patterns, or between the high voltage terminal pattern and a body pattern increases.

### SUMMARY OF THE DISCLOSURE

Accordingly, the present invention has been made to overcome the above problems of the conventional art, and an object of the present invention is to provide a package substrate having a pattern with improved voltage endurance characteristics for a high voltage and an integrated circuit chip having an improved pad.

When a conventional AC-direct type LED drive circuit chip is installed on a substrate using solder and is then operated, the migration region of a high voltage terminal becomes larger than that of a low voltage terminal. As a result, an undesirable short circuit occurs between the high voltage terminal and a thermally conductive pad, and thus there frequently occurs a defect in which the LED drive circuit chip is burnt out.

The problem of the conventional technology in which an undesirable short circuit occurs between the high voltage terminal and an adjacent terminal may be overcome by spacing all the terminals and thermally conductive pad of the chip far apart from one another based on the required spaced distance between the high voltage terminal and the adjacent terminals. However, this simple solution has a problem in that the area of the chip increases, and thus economic efficiency is considerably degraded. Alternatively, in order to ensure required spaced distances between the high voltage terminal and the adjacent terminals and between the high voltage terminal and the thermally conductive pad while maintaining the area of the chip without change, a method of reducing the areas of the conductors of terminals and patterns may be contemplated. However, in this case, there is possibility that required electrical conductivity or thermal conductivity cannot be achieved. That is, when the spaced distance that can prevent the high voltage terminal and the thermally conductive pad from being short-circuited is also applied between common low voltage terminals and the thermally conductive pad, the area of the thermally conductive pad decreases, and thus a problem arises in that the heat dissipation effect of the LED drive circuit chip is reduced.

In particular, in applications, such as an LED drive circuit chip, in which a large amount of heat is generated, thermal control has very important influences on performance and durability, and thus an object of the present invention is to develop the shapes of a substrate and an integrated circuit chip that enable efficient thermal control and that can reduce the causes of defects around a high voltage terminal while maintaining the area of the chip at a low level.

More specifically, an object of the present invention is to provide a substrate and an integrated circuit chip in which the clearance distance between a high voltage terminal and a body pad formed on the integrated circuit chip or between a high voltage terminal pattern and a body pattern formed on the substrate is larger than the clearance distance between the remaining terminals and the body pad or between the remaining terminal patterns and the body pattern.

Furthermore, although the present invention is described using an AC-direct LED integrated circuit chip as an example, the present invention is not limited thereto. An object of the present invention is to provide a solution that can provide an efficient thermal control means without increasing the area of a chip and also can improve voltage endurance characteristics for a high voltage in applications in which a voltage to be applied to a specific pin is higher than voltages to be applied to the remaining pins.

In accordance with an aspect of the present invention, there is provided a substrate with an improved pattern, wherein an integrated circuit chip including a plurality of terminals is installed on the substrate and the substrate includes a plurality of terminal patterns.

In this case, the substrate includes: a body pattern formed to make contact with the body of the integrated circuit chip; at least one first terminal pattern formed to make contact with at least one first terminal to which a voltage higher than voltages to be applied to the remaining terminals of the plurality of terminals is applied; and a second terminal pattern configured to include at least some of remaining terminal patterns other than the at least one first terminal pattern.

Furthermore, in the substrate, a first clearance distance between the first terminal pattern and the body pattern is larger than a second clearance distance between the second terminal pattern and the body pattern.

In the substrate according to a first embodiment of the present invention, a partial region of the body pattern including a portion facing the at least one first terminal pattern may be formed in a recessed shape. The body pattern may be bonded to the body of the integrated circuit chip by soldering material. The body pattern of the integrated circuit chip may be electrically connected to a ground terminal, or may be maintained in a floating state.

The body pattern formed on the substrate of the present invention may be made of material having relatively high thermal conductivity, and may function as a means for dissipating heat generated in the integrated circuit chip installed on the substrate. In this case, the body pattern formed on the substrate of the present invention may be regarded as a thermally conductive pattern.

The substrate according to a second embodiment of the present invention may further include a trench formed between the at least one first terminal pattern and the body pattern. The soldering material within the body pattern between the substrate and the integrated circuit chip may depart from the range of the body pattern when the substrate and the integrated circuit chip are pressed against each other. In this case, when the soldering material moves toward the first terminal pattern, it is blocked by the trench formed between the first terminal pattern and the body pattern, and the spaced distance between the first terminal pattern and the soldering material may be maintained at a level equal to or higher than a reference specification.

The substrate according to a third embodiment of the present invention may further include a bather pattern formed between the at least one first terminal pattern and the body pattern. In this case, the barrier pattern may be made of material having a lower affinity for soldering material than those of the plurality of terminal patterns and the body pattern. In this case, examples of the material of the barrier pattern may include silk and plastic. Since soldering material having viscosity is easily attached to the body pattern but is not easily attached to the barrier pattern, the movement of the soldering material may be blocked by the barrier pattern.

In the substrate according to a fourth embodiment of the present invention, the first boundary line of the body pattern facing the at least one first terminal pattern and the second boundary line of the body pattern facing the second terminal pattern may be located on different surfaces of the body pattern, and the second terminal pattern may be a set of terminals that are formed to face the second boundary line. In this case, the clearance distance may be ensured between the first terminal pattern and the body pattern, and also the overall area of the integrated circuit chip may be maintained without an increase.

In accordance with an aspect of the present invention, there is provided an integrated circuit chip including a plurality of terminals, wherein the integrated circuit chip is installed on a substrate including a plurality of terminal patterns.

In this case, the integrated circuit chip includes: a body pad formed on a surface of the body of the integrated circuit chip facing the substrate; at least one first terminal from among the plurality of terminals and a voltage higher than voltages to be applied to the remaining terminals is applied thereto; and a second terminal including at least some of remaining terminals other than the at least one first terminal.

Furthermore, in the integrated circuit chip, a first clearance distance between the first terminal and the body pad is larger than a second clearance distance between the second terminal and the body pad.

In the integrated circuit chip according to a first embodiment of the present invention, a partial region of the body pad including a portion facing the at least one first terminal may be formed in a recessed shape. The body pad of the integrated circuit chip may be bonded to the patterns on the substrate by soldering material.

The integrated circuit chip according to a second embodiment of the present invention may further include a trench formed between the at least one first terminal and the body pad.

The integrated circuit chip according to a third embodiment of the present invention may further include a bather pattern formed between the at least one first terminal and the body pad. In this case, the bather pattern may be made of material having a lower affinity for soldering material that that of the body pad.

In the integrated circuit chip according to a fourth embodiment of the present invention, the first boundary line of the body pad facing the at least one first terminal and the second boundary line of the body pad facing the second terminal may be located on different surfaces of the body pad, and the second terminal may be a set of terminals that are formed to face the second boundary line.

The body pad formed on the integrated circuit chip of the present invention may perform the function of a thermally conductive pad that dissipates heat that is generated in the integrated circuit chip due to its function.

According to various embodiments of the present invention, the clearance distance can be ensured between the body pad or body pattern and the high voltage terminal or high voltage terminal pattern present between the integrated circuit chip and the substrate. In particular, the clearance distance between a specific region around the high voltage terminal or high voltage terminal pattern and the body pad or body pattern can be selectively increased, and thus efficient thermal control is enabled, voltage endurance characteristics for a high voltage can be improved without a significant change in the overall area of the integrated circuit chip, and also the rate of occurrence of defects can be reduced.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a diagram showing a substrate in which the spaced distance between a region, including a high voltage terminal pattern, and a body pattern according to an embodiment of the present invention;

FIGS. 2A and 2B are diagrams showing substrates in which the spaced distance between a region, including a high voltage terminal pattern, and a body pattern according to embodiments of the present invention;

FIG. 3 is a diagram showing a substrate in which the spaced distance between a partial region, including a high voltage terminal pattern, and a body pattern is long according to an embodiment of the present invention;

FIG. 4 is a diagram showing a substrate in which a barrier pattern is formed between a partial region, including high voltage terminal pattern, and a body pattern according to an embodiment of the present invention;

FIG. 5 is a diagram showing an integrated circuit chip in which the spaced distance between a region, including a high voltage terminal, and a body pad is long according to an embodiment of the present invention;

FIGS. 6A and 6B are diagrams showing integrated circuit chips in which the spaced distance between a high voltage terminal and a body pad is long according to embodiments of the present invention;

FIG. 7 is a diagram showing an integrated circuit chip in which the spaced distance between a partial region, including a high voltage terminal, and a body pad according to an embodiment of the present invention; and

FIG. 8 is a diagram showing a relationship of correspondence between an integrated circuit chip including a high voltage terminal and a substrate including a high voltage terminal pattern according to an embodiment of the present invention.

### DETAILED DESCRIPTION OF THE DISCLOSURE

Hereinafter, embodiments of the present invention will be described in detail with reference to the accompanying drawings. In the following description, detailed descriptions of known elements or functions that may unnecessarily make the gist of the present invention obscure will be omitted.

However, the present invention is limited to or restricted by the embodiments. The same reference symbols denote the same components throughout the accompanying drawings.

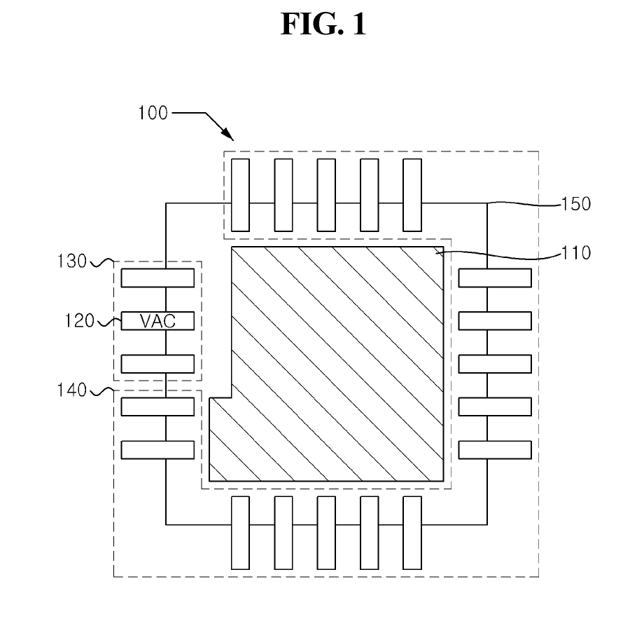

FIG. 1 is a diagram showing a substrate in which the spaced distance between a region, including a terminal to which a high voltage is applied, and a body pattern according to an embodiment of the present invention.

The package substrate is a kind of printed circuit board (PCB). The package substrate may be used for the core semiconductors of mobile devices and PCs, etc. It may transmit electric signals between semiconductors and the main board. Compared with general substrates, as this substrate may be a high-density circuit substrate containing more microcircuits. Further, the assembly defects and incurred costs in directly bonding expensive semiconductors to the substrate can be reduced.

The substrate 100 including a plurality of terminal patterns adapted to connect with a plurality of terminals (not shown) includes: a body pattern 110; a first terminal pattern 120 formed to connect with the first terminal (not shown) of a plurality of terminals to which a high voltage is applied; a first region 130 configured to include the first terminal pattern 120; and a second region 140 configured to include the terminal patterns except the first region 130. The body pattern 110 is configured such that the spaced distance between the first region 130 and the body pattern 110 is larger than the spaced distance between the second region 140 and the body pattern 110. The spaced distance between the first region 130 and the body pattern 110 may be formed to be larger than the spaced distance between the second region 140 and the body pattern 110 by deforming the shape of the part of the body pattern 110 facing the first region 130. When an integrated circuit chip 500 to be described later is installed on the substrate 100, the body pattern 110 is bonded to a body pad 510 formed on the body of the integrated circuit chip 500 by soldering material, thereby forming a heat transfer path through which heat generated in the integrated circuit chip 500 is dissipated.

The spaced distance not only simply refers to a distance in a substrate plane, but also refers to a clearance distance including the height, depth and/or topology of a trench or a heterogeneous material when the trench is formed in a substrate or the heterogeneous material, such as a silken letter, is applied and formed on a substrate.

In the embodiment shown in FIG. 1, the part of the body pattern 110 facing the first region 130 including the first terminal 120 is retreated behind the part of the body pattern 110 facing the second region 140, and thus the spaced distance between the first region 130 and the body pattern 110 is larger than the spaced distance between the second region 140 and the body pattern 110. That is, the boundary line part of the body pattern 110 facing the first region 130 including the first terminal 120 is retreated behind other regions, and thus the clearance distance is ensured between the first terminal 120, i.e., a high voltage terminal, and the body pattern 110. In this case, as the operating condition of the first terminal 120, i.e., a high voltage terminal, is severer—that is, as a maximum voltage applied to the first terminal 120 is higher, an operating frequency is higher, or duration during which the maximum voltage is being applied is larger—the depth to which the part of the body pattern 110 is retrieved may become greater and the width (that is, the width of the first region 130) across which the part of the body pattern 110 is retrieved may become greater. An example of an application in which the operating condition of the first terminal 120 is severe and thermal control is essential may be an AC-direct type LED drive circuit. Since the LED drive circuit generates a large amount of heat, efficient thermal control is essential. In the case of an AC-direct operation, a considerably higher maximum voltage is instantaneously applied to an AC power supply voltage terminal than other terminals. It will be apparent that the spirit of the present invention is not applied only to the AC-direct type LED drive circuit, but may be used as a risk management means for very effective thermal control and a high voltage operation in applications that require efficient thermal control and the management of defects attributable to a high voltage operation.

When an integrated circuit chip (not shown) is installed on the substrate 100, the chip region 150 covered with the integrated circuit chip is shown in the drawing. In this case, the body pattern 110 may be included within the chip region 150. Furthermore, as shown in FIG. 1, some of the plurality of terminal patterns including the first terminal pattern 120 may be included in the chip region 150, and the remainder may be located outside the chip region 150. In another embodiment of the present invention, all the plurality of terminal patterns may be included within the chip region 150.

Furthermore, the first terminal pattern 120 refers to an area where a terminal of the integrated circuit chip having a higher voltage than the plurality of terminal patterns included in the second region 140 is spaced apart. In an embodiment, a ground GND voltage may be applied to the body pattern 110. In another embodiment, the body pattern 110 may be maintained in a floating state.

Furthermore, the material of the substrate 100 may include the material of a common Printed Circuit Board (PCB), circuit board or wiring board, or metallic material (copper, aluminum, or the like). In this case, the metallic material refers to material of high thermal conductivity which is chiefly used to dissipate heat. The fact that the material of a substrate is metallic means that the inner layer of the substrate is metallic. A desirable short circuit can be prevented only when the most region of an outside surface that makes contact with the integrated circuit chip is surrounded by an insulator.

Furthermore, the first region 130 including the first terminal pattern 120 includes terminal patterns adjacent to the first terminal pattern, in which case the number of terminal patterns included in the first region 130 and adjacent to the first terminal pattern may be selectively designated.

After soldering material, such as solder, has been disposed on the body pattern 110, the body pad 510 formed on the body of the integrated circuit chip 500, which will be described later, is bonded to a soldering material layer. Through a later pressing process, the soldering material layer bonds the body pattern 110 of the substrate 100 and the body pad 510 of the integrated circuit chip to each other.

In the pressing process, the soldering material layer may depart from the region of the body pattern 110. As a result, a clearance distance that must be ensured between each terminal pattern and the body pattern 110 is actually reduced due to the soldering material. When this variable is taken into account, a clearance distance of about 0.35 mm is known to be required in the case where a voltage generally applied to the terminal pattern ranges from 30 to 40 V.

When operation is performed at an AC rated voltage of 220 V, a maximum high voltage of 311 V may be instantaneously applied to the first terminal pattern 120 of FIG. 1. In this case, when the spaced distance between the terminal pattern and the body pattern 110 is designed to be 0.35 mm, there is possibility that the distance between the body pattern 110 and the terminal pattern is reduced due to the pressing of the soldering material and a migration phenomenon to be described. In this case, a strong electric field may be formed between the body pattern 110 and the terminal pattern, and thus an undesirable short circuit may occur between the body pattern 110 and the terminal pattern.

Such a short circuit becomes a chief cause of defects. Accordingly, the present invention is intended to reduce the causes of defects during high voltage operation by selectively reducing the clearance distance between the first terminal pattern 120 and the body pattern 110 without influencing the overall area of the integrated circuit chip.

Generally, when a voltage applied between the terminals is switched, a conductor may undergo a migration phenomenon due to chemical, thermal, electrical and mechanical characteristics. According to the migration phenomenon, the conductor may not maintain its initial location and shape, but may be deformed or increased. It is known that the migration phenomenon generally becomes more serious in proportion to the speed of the switching of voltage applied between the terminals and the level of voltage. In the present invention, the soldering material applied between the body pad of the integrated circuit chip and the body pattern 110 of the substrate 100 may undergo the migration phenomenon as a conductor due to the above-described cause.

The body pattern 110 is a type of conductor, and has a heat dissipation effect due to its relatively high thermal conductivity. Since thermal control is very important to applications, such as a drive circuit chip for an LED, that generate a large amount of heat during their operation, the area of the body pattern 110 needs to be equal to or larger than a minimally required specification. The minimally required specification will be designed based on the amount of heat of a relevant application.

Accordingly, in the case where the area of the body pattern 110 must be equal to or larger than the minimally required specification, if long clearance distances must be ensured between the body pattern 110 and all the terminal patterns, the area of the chip region 150 is increased and the size of the integrated circuit chip is increased accordingly, with the result that economic efficiency is degraded.

The present invention is configured such that the clearance distances between the body pattern 110 and the terminal patterns are maintained at a common level in regions in which the clearance distance is not relatively important and such that the shape of the body pattern 110 is deformed such that a sufficient clearance distance can be ensured between the first terminal pattern 120, which makes contact with the first terminal to which a high voltage is applied during operation, and the body pattern 110.

Therefore, according to the present invention, there can be proposed the design of the integrated circuit chip and the substrate that can reduce the occurrence of defects while maximally satisfying a heat dissipation effect in terms of thermal control, a small chip area (economic efficiency), and stability during high voltage operation. Although the case where the first terminal 120, i.e., a high voltage terminal, is one in number has been shown in FIG. 1, the spirit of the present invention is not limited thereto, but may be also applied to cases including a plurality of high voltage terminals.

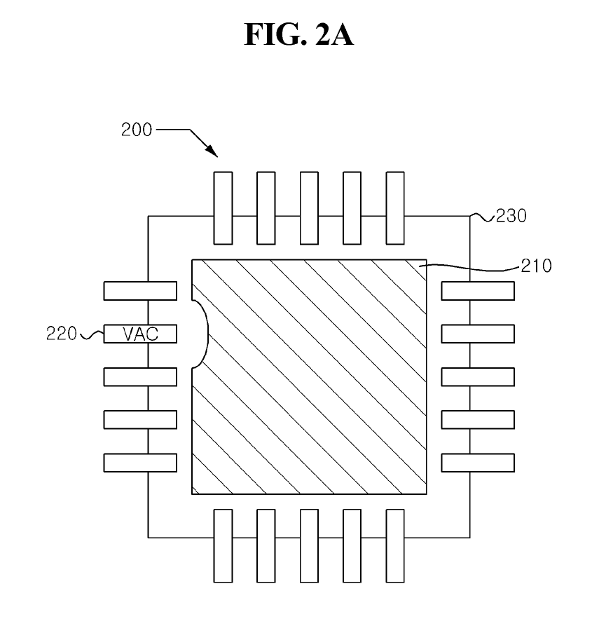

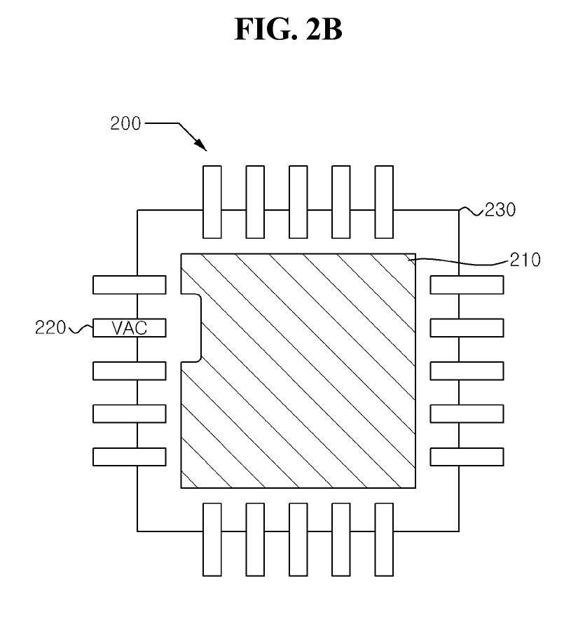

FIGS. 2A and 2B are diagrams showing substrates in which the spaced distance between a terminal, to which a high voltage is applied, and a body pattern is long according to embodiments of the present invention. That is, FIGS. 2A and 2B show embodiments in which a partial region of the body pattern is configured to be recessed. FIGS. 2A and 2B show inventions based on substantially the same concept except only that the shapes of the recessed regions of body patterns are different, the same reference symbols are applied to both FIG. 2A and 2B for ease of description.

Substrates 200 each including a plurality of terminals according to the present embodiments are configured such that each of the substrates 200 includes a body pattern 210 and a first terminal pattern 220 from among the plurality of terminals and a high voltage is applied thereto, and such that the spaced distance between the first terminal pattern 220 and the body pattern 210 is larger than the spaced distance between the plurality of terminal patterns except for the first terminal pattern 220 and the body pattern 210.

In this case, the shape of the body pattern 210 may be designated and formed in accordance with the first terminal pattern 220. That is, as shown in FIG. 2A, the part of the body pattern 210 facing the first terminal pattern 220 may be formed in a semicircular shape so that only the spaced distance between the first terminal pattern 220 and the body pattern 210 is larger than the spaced distance between the plurality of terminal patterns except for the first terminal pattern 220 and the body pattern 210. In contrast, as shown in FIG. 2B, the part of the body pattern 210 facing the first terminal pattern 220 may be formed in a rounded rectangular shape in order to increase only the spaced distance between the first terminal pattern 220 and the body pattern 210. In this case, the depth and width to and across which the part of the body pattern 210 is retrieved may be increased in proportion to the severeness of the operating condition of the first terminal 220, i.e., a high voltage terminal.

Also in FIGS. 2A and 2B, the body pattern 210 may be electrically connected to a ground GND in an embodiment, or the body pattern 210 may be in a floating state in another embodiment. That is, the body pattern 210 does not necessarily need to be grounded.

Also in FIGS. 2A and 2B, there is shown a chip region 230 that is covered with an integrated circuit chip when the integrated circuit chip is installed on the substrate 200. According to the embodiments of FIGS. 2A and 2B, it is possible to selectively increase the clearance distance between the first terminal pattern 220 and the body pattern 210 while maintaining the area of the chip region 230 at a low level, thereby reducing the causes of defects during high voltage operation.

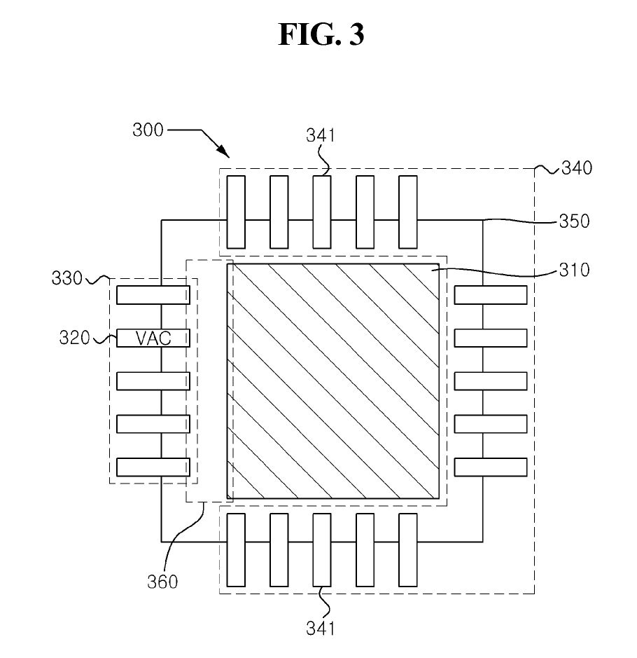

FIG. 3 is a diagram showing a substrate in which the spaced distance between a partial region, including a terminal to which a high voltage is applied, and a body pattern is long according to an embodiment of the present invention.

A substrate 300 including a plurality of terminals according to the present embodiment includes a body pattern 310, a first terminal pattern 320 from among the plurality of terminals and a high voltage is applied thereto, a first region 330 configured to include the first terminal pattern 320, and a second region 340 configured to include terminal patterns 341 other than the first region 330. The body pattern 310 is configured such that the spaced distance between the first region 330 including the first terminal pattern 320 and the body pattern 310 is larger than the spaced distance between the second region 340 and the body pattern 310.

In this case, the first region 330 refers to a partial region including the first terminal pattern 320 on the substrate 300. Depending on an embodiment, the first region 330 may further include terminal patterns adjacent to the first terminal pattern 320, as shown in FIG. 3. The spaced distance between the first region 330 and the adjacent body pattern 310 may be formed by taking into account an area that can minimize a reduction in the performance of the body pattern 310.

A gap area 360 located between the first region 330, including the first terminal pattern 320, and the body pattern 310 in FIG. 3 may be designed by taking into account at least one of a voltage range to be applied to the first terminal pattern 320, a maximum instantaneous voltage, and duration during which the maximum instantaneous voltage continues. That is, the width of the gap area 360 corresponds to the clearance distance between the first region 330 and the body pattern 310, and thus the width of the gap area 360 may be designed in proportion to the severeness of a high voltage condition that is applied to the first terminal pattern 320.

Also in FIG. 3, the body pattern 310 may be electrically connected to a ground GND in an embodiment, or may be in a floating state in another embodiment. That is, the body pattern 310 does not necessarily need to be grounded.

Also in FIG. 3, there is shown a chip region 350 that is covered with an integrated circuit chip when the integrated circuit chip is installed on the substrate 300. According to the embodiment of FIG. 3, it is possible to selectively increase the clearance distance between the first terminal pattern 320 and the body pattern 310 while maintaining the area of the chip region 350 at a low level, thereby reducing the causes of defects during high voltage operation.

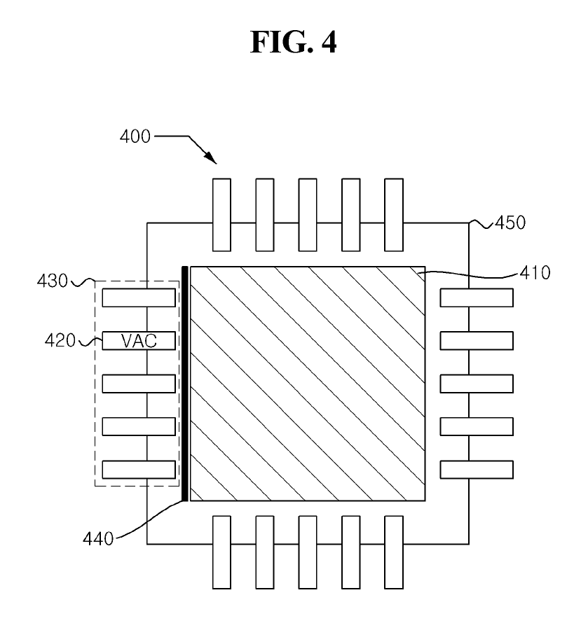

FIG. 4 is a diagram showing a substrate in which a barrier pattern is formed between a partial region, including a terminal to which a high voltage is applied, and a body pattern according to an embodiment of the present invention.

A substrate 400 including a plurality of terminals according to the present embodiment includes a body pattern 410, a first terminal pattern 420 from among the plurality of terminals and a high voltage is applied thereto, and a first region 430 configured to include a first terminal pattern 420. The body pattern 410 is configured such that a bather pattern 440 is formed between the first region 430, including the first terminal pattern 420, and the body pattern 410.

In this case, the bather pattern 440 may be implemented by applying a heterogeneous material, such as a letter made of silk or plastic, and must be made of insulating material through which electricity is not conducted. Furthermore, the barrier pattern 440 may be made of material having a lower affinity for soldering material, such as solder, than those of the body pattern 410 and the terminal patterns 420 and 430.

In this case, the bather pattern 440 is not necessarily formed to have a thickness that is sufficient to form a barrier. Soldering material, such as solder, has intrinsic viscosity, and thus the soldering material may depart from the body pattern 410 and move toward the first terminal pattern 420 in some cases when an integrated circuit chip (not shown) and the substrate 400 are pressed against each other. In this case, the presence of the barrier pattern 440 that is electrically insulative and has a lower affinity for the soldering material than the body pattern 410 may prevent the soldering material having viscosity from moving.

That is, in this case, the clearance distance between the first terminal pattern 420 and the body pattern 410 may have a value obtained by adding the thickness of the barrier pattern 440 to a rectilinear line distance in a substrate plane. An effective clearance distance based on the physical properties of the barrier pattern 440 may have a value larger than that of the physical clearance distance. Since the barrier pattern 440 is electrically insulating and has a lower affinity for the soldering material than the body pattern 410, the soldering material having viscosity moves slower on the barrier pattern 440 than on the body pattern 410. In this case, the physical clearance distance that the soldering material undergoes while moving may be a distance obtained by adding the thickness of the barrier pattern 440 to the rectilinear line distance between the first terminal pattern 420 and the body pattern 410. The effective clearance distance may refer to a distance that is determined by additionally taking into account the obstruction of movement attributable to viscosity that the soldering material undergoes while moving on the barrier pattern 440. In this case, the soldering material may undergo the effective clearance distance larger than the physical clearance distance to the extent that the movement of the soldering material becomes difficult due to the low affinity between the soldering material and the barrier pattern 440.

Furthermore, although the barrier pattern 440 is shown as being formed in FIG. 4, a trench may be formed at the same location in another embodiment of the present invention. In the case where the trench is formed between the first region 430 and the body pattern 410, even when solder overflows out of the body pattern 410 and thus the first region 430 and the body pattern 410 become closer to each other, the movement of the solder is blocked by the trench, thereby preventing the first region 430 and the body pattern 410 from influencing each other. In this case, the clearance distance may have a value obtained by adding the depth of the trench to a rectilinear line distance in a substrate plane.

Although the body pattern 410 is shown as being electrically connected to a ground GND also in FIG. 4, the body pattern 410 may be in a floating state in an embodiment, but does not necessarily need to be grounded.

In the embodiment of FIG. 4, the thickness of the barrier pattern 440 may be in proportion to the severeness of a high voltage condition that is applied to the first terminal pattern 420, and the affinity of the material of the barrier pattern 440 for the soldering material may be in inverse proportion to the severeness of the high voltage condition. Furthermore, when the bather pattern 440 is a trench, the depth of the trench may be in proportion to the severeness of the high voltage condition.

Also in FIG. 4, there is shown a chip region 450 that is covered with an integrated circuit chip when the integrated circuit chip is installed on the substrate 400. According to the embodiment of FIG. 4, it may be possible to selectively increase the clearance distance between the first terminal pattern 420 and the body pattern 410 while maintaining the area of the chip region 450 at a low level, thereby reducing the causes of defects during high voltage operation.

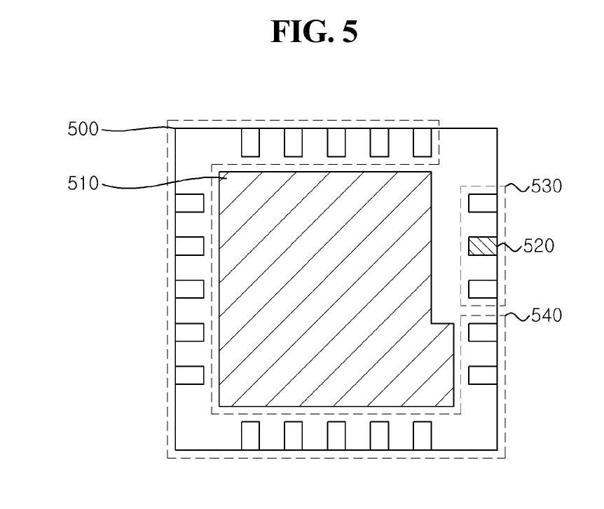

FIG. 5 is a diagram showing an integrated circuit chip in which the spaced distance between a region, including a terminal to which a high voltage is applied, and a body pad is long according to an embodiment of the present invention. Referring to FIG. 5, the case of Quad-Flat No-leads (QFN)-type packaging is shown. The QFN-type packaging is characterized in that leads are not exposed to the outside and are formed inside a chip. Furthermore, Dual-Flat No-leads (DFN)-type packaging is configured such that leads are not exposed to the outside like the QFN-type packaging. However, the spirit of the present invention is not limited only to the QFN and DFN-type packaging, but may be also applied to packaging in which leads are exposed to the outside.

An integrated circuit chip 500 including a plurality of terminals includes a body pad 510, a first terminal 520 from among the plurality of terminals and a high voltage is applied thereto, a first terminal group 530 configured to include the first terminal 520, and a second terminal group 540 configured to include terminal patterns other than the first terminal group 530. The body pad 510 is configured such that the spaced distance between the first terminal group 530 and the body pad 510 is larger than the spaced distance between the second terminal group 540a and the body pad 510. The part of the body pad 510 facing the first terminal group 530 may be retrieved behind the part of the body pad 510 facing the second terminal group 540, and thus the spaced distance between the first terminal group 530 and the body pad 510 may be formed to be larger than the spaced distance second between the terminal group 540 and the body pad 510.

In this case, the spaced distance not only simply refers to a distance in a substrate plane, but also refers to a clearance distance including the height of a trench or a heterogeneous material when the trench is formed in a substrate or the heterogeneous material, such as a silken letter, is applied and formed on a substrate.

Furthermore, the first terminal 520 refers to a terminal having a higher voltage than a plurality of terminals included in the second terminal group 540. In an embodiment, a ground GND voltage may be applied to the body pattern 510. In another embodiment, the body pattern 110 may be maintained in a floating state.

Furthermore, the integrated circuit chip 500 generally refers to a semiconductor device, or may be an AC-direct LED drive chip. That is, the present invention is intended to prevent an undesirable short circuit phenomenon attributable to a high voltage when the high voltage is instantaneously or continuously applied only to a specific terminal, and thus the present invention may be applied to any type of application in which a high voltage is instantaneously or continuously applied only to a specific terminal.

The integrated circuit chip 500 shown in FIG. 5 may be installed on the substrate 100 shown in FIG. 1. That is, the body pad 510 of the integrated circuit chip 500 may be bonded to the body pattern 110 on the substrate 100 by soldering material, and the terminals of the integrated circuit chip 500 may be bonded to the terminal patterns on the substrate 100 by soldering material. More specifically, the first terminal pattern 120 and the first terminal 520 may be bonded to each other by soldering material.

As shown in FIG. 5, the terminals preferably correspond to the respective terminal patterns within the chip region 150 on the substrate 100 shown in FIG. 1, and the shape of the body pad 510 of FIG. 5 preferably corresponds to that of the body pattern 110 of FIG. 1. However, in an embodiment, the shape of the body pad 510 does not necessarily need to correspond to that of the body pattern 110.

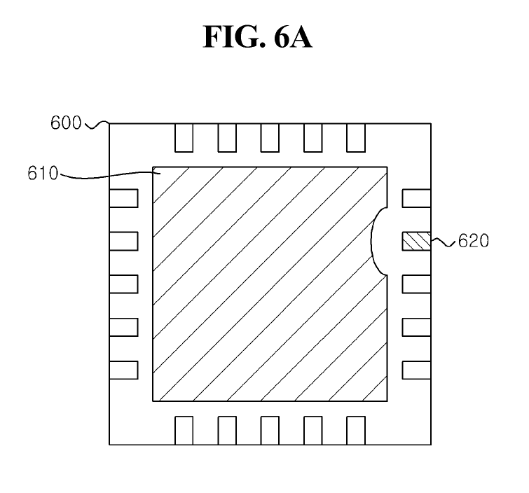

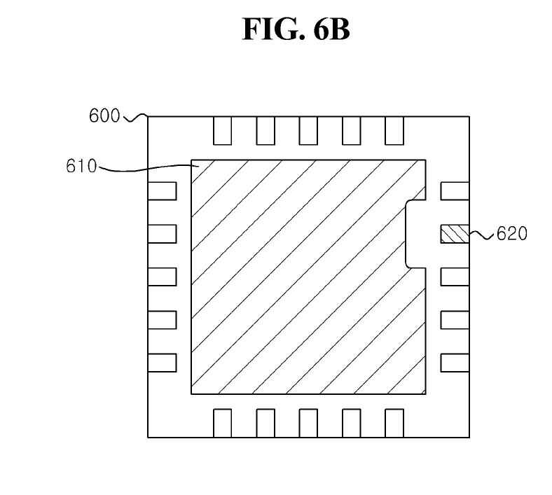

FIGS. 6A and 6B are diagrams showing integrated circuit chips in which the spaced distance between a terminal, to which a high voltage is applied, and a body pad is long according to embodiments of the present invention.

Integrated circuit chips 600 each including a plurality of terminals according to the present embodiments are configured such that each of the integrated circuit chips 600 includes a body pad 610 and a first terminal 620 from among the plurality of terminals and a high voltage is applied thereto. The body pad 610 is configured such that the spaced distance between the first terminal 620 and the body pad 610 is larger than the spaced distance between a plurality of terminals other than the first terminal 620 and the body pad 610.

In this case, the shape of the body pad 610 may be deformed in accordance with the first terminal 620. As shown in FIG. 6A, the part of the body pad 610 facing the first terminal 620 may be retrieved in a semicircular shape so that only the spaced distance between the first terminal 620 and the body pad 610 is larger than the spaced distance between the terminals, other than the first terminal, and the body pad 610. In contrast, as shown in FIG. 6B, the part of the body pad 610 facing the first terminal 620 is retrieved in a rounded rectangular shape so that only the spaced distance between the first terminal 620 and the body pad 610 is larger than the spaced distance between the terminals, other than the first terminal, and the body pad 610.

In an embodiment, a ground GND voltage may be applied to the body pad 610. In another embodiment, the body pad 610 may be maintained in a floating state.

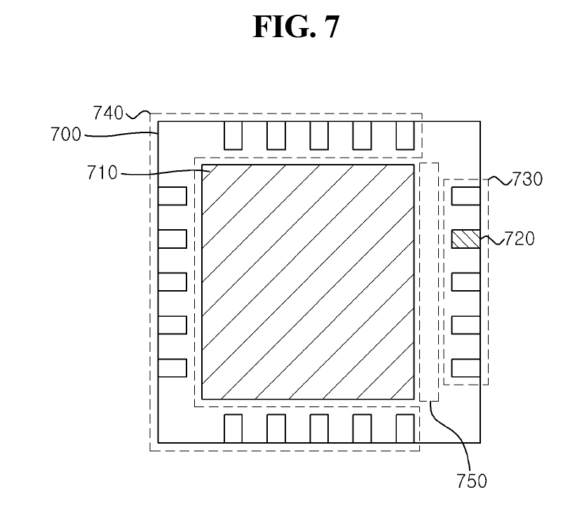

FIG. 7 is a diagram showing an integrated circuit chip in which the spaced distance between a partial region, including a terminal to which a high voltage is applied, and a body pad according to an embodiment of the present invention.

An integrated circuit chip 700 including a plurality of terminals according to the present embodiment is configured such that it includes a body pad 710, a first terminal 720 from among a plurality of terminals and a high voltage is applied thereto, a partial region 730 including the first terminal 720, and regions 740 other than the partial region 730 including the first terminal 720 and such that the spaced distance between the partial region 730, including the first terminal 720, and the body pad 710 is formed to be larger than the spaced distance between the other regions 740 and the body pad 710.

In this case, the area of the body pad 710 may be adjusted to minimize reduction in the intrinsic performance of the body pad 710. For example, when the body pad 710 is a ground GND, the area of the body pad 710 may be designed to be maintained at a level equal to or larger than a minimum area in order to reliably perform its ground function.

In addition to the above-described various embodiments, still another embodiment of the present invention provides an integrated circuit chip in which a barrier pattern or trench may be formed between a body pad and a first terminal to which a high voltage is applied and thus the clearance distance may be selectively ensured between the body pad and the first terminal.

Furthermore, although in the substrates 100, 200 and 300 of FIGS. 1 to 3 and the integrated circuit chips 500, 600 and 700 of FIGS. 5 to 7, it is preferred that the shape of the body pattern 110, 210 or 310 on each of the substrates 100, 200 and 300 be identical to or be substantially identical to the body pad 510, 610 or 710 on the corresponding one of the integrated circuit chips 500, 600 and 700, the spirit of the present invention is not limited thereto. For example, although the integrated circuit chip 500 of FIG. 5 and the substrate 100 of FIG. 1 may be used together, the integrated circuit chip 500 of FIG. 5 and the substrate 200 of FIG. 2 or substrate 300 of FIG. 3 may be bonded and used together.

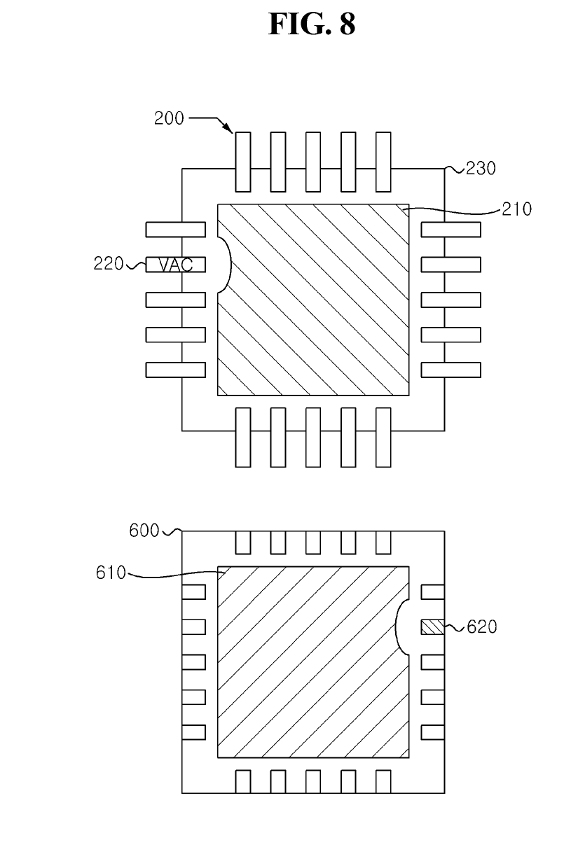

FIG. 8 is a diagram showing a relationship of correspondence between an integrated circuit chip including a high voltage terminal and a substrate including a high voltage terminal pattern according to an embodiment of the present invention.

Referring to FIG. 8, an integrated circuit chip 600 corresponds to a chip region 230 on a substrate 200. When the integrated circuit chip 600 is installed on the substrate 200, the chip region 200 is covered with the integrated circuit chip 600. In this case, the body pad 610 of the integrated circuit chip 600 is bonded to the body pattern 210 on the substrate 200 by soldering material. Furthermore, a first terminal 620, i.e., a high voltage terminal, is bonded to a first terminal pattern 220 on the substrate 200 by soldering material. The part of the body pad 610 facing the first terminal 620 may be recessed (retrieved) in a semicircular shape, and the part of the body pattern 210 facing the first terminal pattern 220 may also be recessed (retrieved) in a semicircular shape.

According to the present invention, a substrate and an integrated circuit chip having a pattern with improved voltage endurance characteristics for a high voltage terminal can be implemented.

Furthermore, according to the present invention, a substrate and an integrated circuit chip that can provide an efficient thermal control means and also have efficiently improved voltage endurance characteristics for a high voltage while maintaining the area of the integrated circuit chip without an increase.

Furthermore, according to the present invention, the clearance distances between the high voltage terminal and the body pad and between the high voltage terminal pattern and the body pattern can be effectively ensured, and thus the rate of occurrence of failures, such as an undesirable short circuit, attributable to an excess of soldering material can be reduced.

Furthermore, according to the present invention, a high voltage terminal or a region including a high voltage terminal can be designated and then a clearance distance can be ensured, and the body pad can reliably function as a light emission pattern not matter what it is a ground GND or is in a floating state.

The body pad on the bottom surface of the integrated circuit chip or the body pattern formed on the top surface of the substrate bonded to the integrated circuit chip has a heat dissipation effect. That is, in an application in which a large amount of heat is generated, thermal control corresponds to a very important specification, and thus the size of the body pad on the bottom surface of the integrated circuit chip or body pattern formed on the top surface of the substrate needs to be maintained at a predetermined or higher level. In this case, it is efficient in terms of thermal control to maintain the clearance distance between the boundary line of the body pad and the terminal of the integrated circuit chip or between the body pattern and the terminal pattern on the substrate at a minimum level within a range in which the required specification is satisfied.

According to the present invention, the design of a substrate and an integrated circuit chip that can reduce the causes of occurrence of defects is proposed in light of a chip area (economic efficiency), thermal control, and stability during high voltage operation.

Furthermore, according to the present invention, there can be implemented a solution that is not limited to a specific application, such as an AC-direct LED integrated circuit chip or the like, and that can improve voltage endurance characteristics for a high voltage without increasing the area of a chip in applications in which a voltage to be applied to a specific pin is higher than voltages to be applied to the remaining pins. Furthermore, according to the present invention, there can be designed a substrate and an integrated circuit chip that can reduce the causes of occurrence of defects during operation in applications in which a large amount of heat is generated and the operation voltage range of a specific terminal is wide.

As described above, although the present invention has been described in conjunction with specific details, such as specific elements and limited embodiments and drawings, these are provided merely to help the overall understanding of the present invention. The present invention is not limited to these embodiments, and various modifications and variations can be made based on the foregoing description by those having ordinary knowledge in the art to which the present invention pertains.

Accordingly, the technical spirit of the present invention should not be defined based on only the described embodiments, and the following claims, all equivalents to the claims and equivalent modifications should be construed as falling within the scope of the spirit of the present invention.

What is claimed is:

1. A substrate including a plurality of terminal patterns, an integrated circuit chip including a plurality of terminals being installed on the substrate, the substrate comprising:
a body pattern formed at a location makes contact with a body of the integrated circuit chip;
at least one first terminal pattern formed at a location makes contact with at least one first terminal, from among the plurality of terminals, a first voltage is applied thereto; and
a second terminal pattern configured to include at least a part of remaining terminal patterns other than the at least one first terminal pattern;
wherein the first voltage is a voltage higher than voltages to be applied to the remaining terminals other than the at least one first terminal; and
wherein a first clearance distance between the first terminal pattern and the body pattern is larger than a second clearance distance between the second terminal pattern and the body pattern.

2. The substrate of claim 1, wherein a partial region of the body pattern including a portion facing the at least one first terminal pattern is formed in a recessed shape.

3. The substrate of claim 1, further comprising a trench formed between the at least one first terminal pattern and the body pattern.

4. The substrate of claim 1, further comprising a barrier pattern formed between the at least one first terminal pattern and the body pattern.

5. The substrate of claim 4, wherein the barrier pattern has a lower affinity for soldering material than the plurality of terminal patterns and the body pattern.

6. The substrate of claim 1, wherein a first boundary line of the body pattern facing the at least one first terminal pattern and a second boundary line of the body pattern facing the second terminal pattern are located on different surfaces of the body pattern, and the second terminal pattern is a set of terminals that are formed to face the second boundary line.

7. The substrate of claim 1, wherein the body pattern is bonded to the body of the integrated circuit chip by soldering material.

8. An integrated circuit chip including a plurality of terminals, the integrated circuit chip being installed on a substrate including a plurality of terminal patterns, the integrated circuit chip comprising:
a body pad formed on a surface of a body of the integrated circuit chip facing the substrate;
at least one first terminal, from among the plurality of terminals, a first voltage is applied thereto; and
a second terminal including at least a part of remaining terminals other than the at least one first terminal;
wherein the first voltage is a voltage higher than voltages to be applied to the remaining terminals other than the at least one first terminal; and
wherein a first clearance distance between the first terminal and the body pad is larger than a second clearance distance between the second terminal and the body pad.

9. The integrated circuit chip of claim 8, wherein a partial region of the body pad including a portion facing the at least one first terminal is formed in a recessed shape.

10. The integrated circuit chip of claim 8, further comprising a trench formed between the at least one first terminal and the body pad.

11. The integrated circuit chip of claim 8, further comprising a barrier pattern formed between the at least one first terminal and the body pad.

12. The integrated circuit chip of claim 11, wherein the barrier pattern has a lower affinity for soldering material than the body pad.

13. The integrated circuit chip of claim 8, wherein a first boundary line of the body pad facing the at least one first terminal and a second boundary line of the body pad facing the second terminal are located on different surfaces of the body pad, and the second terminal is a set of terminals that are formed to face the second boundary line.

14. The integrated circuit chip of claim 8, wherein the body pad is bonded to the patterns on the substrate, including the plurality of terminal patterns, by soldering material.
